(19) United States
(12) Patent Application Publication
(10) Pub. No.: US 2026/0058609 A1
(43) Pub. Date: Feb. 26, 2026

(54) DOHERTY AMPLIFIER

(71) Applicant: Murata Manufacturing Co., Ltd., Nagaokakyo-shi (JP)

(72) Inventor: Hideyuki SATO, Nagaokakyo-shi (JP)

(73) Assignee: Murata Manufacturing Co., Ltd., Nagaokakyo-shi (JP)

(21) Appl. No.: 19/375,965

(22) Filed: Oct. 31, 2025

Related U.S. Application Data
(63) Continuation of application No. PCT/JP2024/014718, filed on Apr. 11, 2024.

(30) Foreign Application Priority Data
Jul. 28, 2023 (JP) 2023-123313

(51) Int. Cl. H03F 1/02; H01L 23/00; H01L 23/66; H03F 3/68; H05K 1/18

(52) U.S. Cl. CPC H03F 1/0288; H01L 23/66; H01L 24/16; H03F 3/68; H05K 1/181; H01L 2223/6616; H01L 2223/6644; H01L 2223/6672; H01L 2224/16235; H01L 2924/1421; H03F 2200/09; H03F 2200/451; H05K 2201/10098

(57) ABSTRACT

A Doherty amplifier includes a carrier amplifier and a peak amplifier. Each of the carrier amplifier and the peak amplifier is a differential amplifier including a first phase amplifier and a second phase amplifier. The Doherty amplifier also includes a balun configured to synthesize an output signal of the carrier amplifier and an output signal of the peak amplifier. The carrier amplifier and the peak amplifier are formed in an integrated circuit. The balun is formed on a printed wiring board on which the integrated circuit is mounted.

### CROSS REFERENCE TO RELATED APPLICATION

This is a continuation of International Application No. PCT/JP2024/014718 filed on Apr. 11, 2024 which claims priority from Japanese Patent Application No. 2023-123313 filed on Jul. 28, 2023. The contents of these applications are incorporated herein by reference in their entireties.

### BACKGROUND OF THE DISCLOSURE

### Field of the Disclosure

The present disclosure relates to a Doherty amplifier.

### Description of the Related Art

As a highly efficient power amplifier, a Doherty amplifier is known. In general, the Doherty amplifier has a structure in which a carrier amplifier configured to operate independently of a power level of an input signal and a peak amplifier configured to turn off at a small power level of the input signal and turn on at a large power level of the input signal are connected in parallel. In this structure, when the power level of a radio-frequency input signal is large, the carrier amplifier operates while maintaining a saturation at a saturated output power level. Thus, the Doherty amplifier can improve the efficiency compared to a usual power amplifier.

Japanese Unexamined Patent Application Publication No. 2013-85179 described below (especially, see FIG. 5) describes a Doherty power amplifier of a differential current synthesization-type. This Doherty power amplifier includes a carrier amplifier that is a differential amplifier and a peak amplifier that is also a differential amplifier, a phase shifter provided between an output terminal of the carrier amplifier and an output terminal of the peak amplifier, and a transformer configured to synthesize an output signal of the carrier amplifier and an output signal of the peak amplifier and output the synthesized signal.

### BRIEF SUMMARY OF THE DISCLOSURE

Implementation of the Doherty amplifier of the differential current synthesization-type described in Japanese Unexamined Patent Application Publication No. 2013-85179 is discussed. For example, the carrier amplifier and the peak amplifier are formed on an integrated circuit (IC). This IC is mounted on a printed wiring board (PWB). Thus, the Doherty amplifier of the differential current synthesization-type described in Japanese Unexamined Patent Application Publication No. 2013-85179 is implemented as a printed circuit board (PCB). However, in this case, the output characteristics may degrade depending on a layout of wiring.

The present disclosure is made in view of the above-described situation and is aimed at suppressing degradation of output characteristics of a Doherty amplifier.

A Doherty amplifier according to an aspect of the present disclosure includes a carrier amplifier and a peak amplifier. Each of the carrier amplifier and the peak amplifier is a differential amplifier including a first phase amplifier and a second phase amplifier. The Doherty amplifier also includes a balun configured to synthesize an output signal of the carrier amplifier and an output signal of the peak amplifier. The carrier amplifier and the peak amplifier are formed in an integrated circuit. The balun is formed on a printed wiring board on which the integrated circuit is mounted. When a first wiring electrically connects an output terminal of the first phase amplifier of the carrier amplifier and an output terminal of the first phase amplifier of the peak amplifier to each other, and a second wiring electrically connects an output terminal of the second phase amplifier of the carrier amplifier and an output terminal of the second phase amplifier of the peak amplifier to each other, one of the first wiring and the second wiring is formed on the printed wiring board and another of the first wiring and the second wiring is formed in the integrated circuit.

According to the present disclosure, degradation of the output characteristics of the Doherty amplifier can be suppressed.

### BRIEF DESCRIPTION OF THE SEVERAL VIEWS OF THE DRAWINGS

FIG. 1 illustrates a circuit configuration common to a Doherty amplifier of a first embodiment and a Doherty amplifier of a comparative example.

FIG. 2 illustrates a layout of a Doherty amplifier according to a first comparative example.

FIG. 3 illustrates a layout of a Doherty amplifier according to a second comparative example.

FIG. 4 illustrates a layout of a Doherty amplifier according to the second comparative example.

FIG. 5 illustrates a layout of the Doherty amplifier according to the first embodiment.

FIG. 6 illustrates the layout of the Doherty amplifier according to the first embodiment.

FIG. 7 is an equivalent circuit diagram focusing on the inductance of the Doherty amplifier according to the first embodiment.

FIG. 8 illustrates a layout of a Doherty amplifier according to a second embodiment.

FIG. 9 illustrates the layout of the Doherty amplifier according to the second embodiment.

FIG. 10 is an equivalent circuit diagram focusing on the inductance of the Doherty amplifier according to the second embodiment.

### DETAILED DESCRIPTION OF THE DISCLOSURE

Hereinafter, embodiments of the present disclosure will be described in detail with reference to the drawings. The embodiments do not limit the present disclosure. Of course, each embodiment is exemplary, and configurations in different embodiments can be partially replaced or combined. In and after the second embodiment, description of items in common with the first embodiment is omitted. Only items different from those of the first embodiment will be described. In particular, similar operations and effects with similar configurations are not described on an embodiment-by-embodiment basis.

### First Embodiment

### Circuit Configuration Common to First Embodiment and Comparative Example

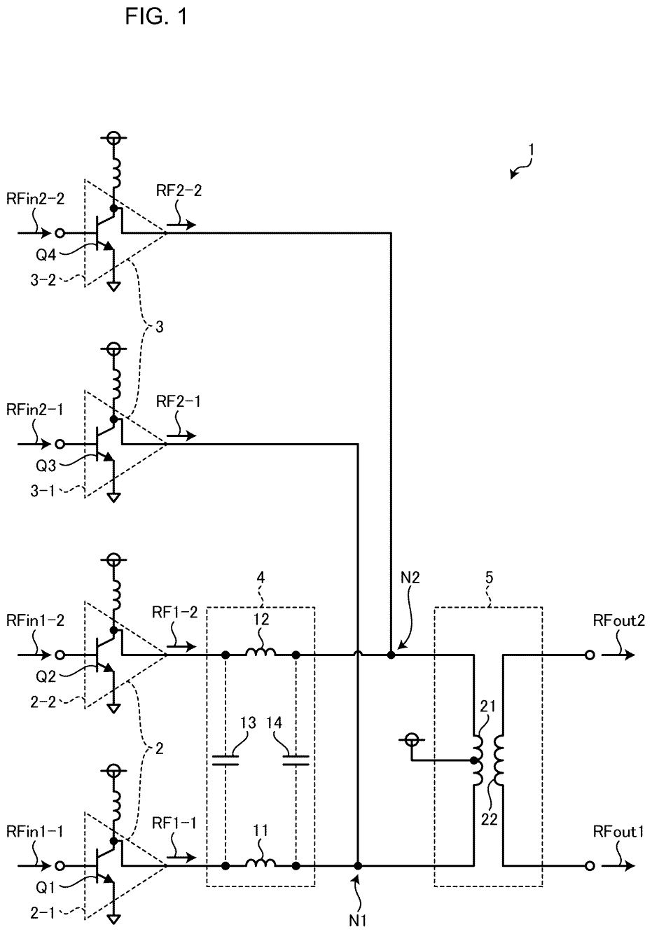

FIG. 1 illustrates a circuit configuration common to a Doherty amplifier of the first embodiment and a Doherty amplifier of a comparative example.

A Doherty amplifier 1 is a differential amplifier. A first phase radio frequency signal RFin1-1 and a second phase radio frequency signal RFin1-2 serving as first differential signals are inputted to the Doherty amplifier 1. Furthermore, a first phase radio frequency signal RFin2-1 and a second phase radio frequency signal RFin2-2 serving as second differential signals are inputted to the Doherty amplifier 1. The Doherty amplifier 1 amplifies from the first phase radio frequency signal RFin1-1 to the second phase radio frequency signal RFin2-2 and outputs a first phase high frequency signal RFout1 and a second phase radio frequency signal RFout2 serving as differential signals.

The Doherty amplifier 1 includes a carrier amplifier 2, a peak amplifier 3, a phase shifter 4, and a balun 5.

Each of the carrier amplifier 2 and the peak amplifier 3 is a differential amplifier. The carrier amplifier 2 includes a first phase amplifier 2-1 and a second phase amplifier 2-2. The peak amplifier 3 includes a first phase amplifier 3-1 and a second phase amplifier 3-2.

Although the first phase is a positive phase (positive polarity) and the second phase is a negative phase (negative polarity) according to the embodiment, the present disclosure is not limited to this. The first phase may be a negative phase, and the second phase may be a positive phase.

The first phase amplifier 2-1 of the carrier amplifier includes a transistor Q1. The emitter of the transistor Q1 is electrically connected to a reference potential. Although a ground potential exemplifies the reference potential, the present disclosure is not limited to this. The first phase radio frequency signal RFin1-1 and a base bias current (not illustrated) are inputted to the base of the transistor Q1. The collector of the transistor Q1 is electrically connected to a power source potential via a choke coil. The power source can be supplied from a first winding 21, which will be described later, of the balun 5 to the collector of the transistor Q1. Thus, the choke coil is not necessarily provided. The transistor Q1 amplifies the first phase radio frequency signal RFin1-1 inputted to the base and outputs the amplified first phase radio frequency signal RF1-1 from the collector.

Although each transistor is a bipolar transistor according to the present disclosure, the present disclosure is not limited to this. Although a heterojunction bipolar transistor (HBT) exemplifies the bipolar transistor, the present disclosure is not limited to this. The transistor may be, for example, a field effect transistor (FET). The transistor may be a multi-finger transistor in which a plurality of unit transistors are electrically connected in parallel. The unit transistor refers to a minimum configuration of a transistor.

When each transistor is an FET, the source corresponds to the emitter of the bipolar transistor, the gate corresponds to the base of the bipolar transistor, and the drain corresponds to the collector of the bipolar transistor.

The second phase amplifier 2-2 of the carrier amplifier includes a transistor Q2. The emitter of the transistor Q2 is electrically connected to the reference potential. The second phase radio frequency signal RFin1-2 and the base bias current (not illustrated) are inputted to the base of the transistor Q2. The collector of the transistor Q2 is electrically connected to the power source potential via a choke coil. The power source can be supplied from the first winding 21, which will be described later, of the balun 5 to the collector of the transistor Q2. Thus, the choke coil is not necessarily provided. The transistor Q2 amplifies the second phase radio frequency signal RFin1-2 inputted to the base and outputs the amplified second phase radio frequency signal RF1-2 from the collector.

The first phase amplifier 3-1 of the peak amplifier includes a transistor Q3. The emitter of the transistor Q3 is electrically connected to the reference potential. The first phase radio frequency signal RFin2-1 and the base bias current (not illustrated) are inputted to the base of the transistor Q3. The collector of the transistor Q3 is electrically connected to the power source potential via a choke coil. The power source can be supplied from the first winding 21, which will be described later, of the balun 5 to the collector of the transistor Q3. Thus, the choke coil is not necessarily provided. The transistor Q3 amplifies the first phase radio frequency signal RFin2-1 inputted to the base and outputs the amplified first phase radio frequency signal RF2-1 from the collector.

The second phase amplifier 3-2 of the peak amplifier includes a transistor Q4. The emitter of the transistor Q4 is electrically connected to the reference potential. The second phase radio frequency signal RFin2-2 and the base bias current (not illustrated) are inputted to the base of the transistor Q4. The collector of the transistor Q4 is electrically connected to the power source potential via a choke coil. The power source can be supplied from the first winding 21, which will be described later, of the balun 5 to the collector of the transistor Q4. Thus, the choke coil is not necessarily provided. The transistor Q4 amplifies the second phase radio frequency signal RFin2-2 inputted to the base and outputs the amplified second phase radio frequency signal RF2-2 from the collector.

The phase shifter 4 includes an inductors 11 and 12. The inductor 11 and the inductor 12 can be implemented with transmission lines (for example, wiring). The phase shifter 4 may further include a capacitor 13 and a capacitor 14.

When the phase shifter 4 includes the capacitors 13 and 14, one end of the capacitor 13 is electrically connected to one end of the inductor 11, and another end of the capacitor 13 is electrically connected to one end of the inductor 12. Furthermore, one end of the capacitor 14 is electrically connected to another end of the inductor 11, and another end of the capacitor 14 is electrically connected to another end of the inductor 12.

When the phase shifter 4 includes the capacitors 13 and 14, the capacitors 13 and 14 may be formed in an integrated circuit 31 (IC, described later) or formed on a printed wiring board 32 (described later).

The one end of the inductor 11 is electrically connected to the collector of the transistor Q1. The other end of the inductor 11 is electrically connected to a node N1. The inductor 11 delays the phase of the first phase radio frequency signal RF1-1 and outputs it to the node N1.

The one end of the inductor 12 is electrically connected to the collector of the transistor Q2. The other end of the inductor 12 is electrically connected to a node N2. The inductor 12 delays the phase of the second phase radio frequency signal RF1-2 and outputs it to the node N2.

The collector of the transistor Q3 is electrically connected to the node N1. In the node N1, the first phase radio frequency signal RF1-1 having passed through the phase shifter 4 and the first phase radio frequency signal RF2-1 are superposed on each other.

The collector of the transistor Q4 is electrically connected to the node N2. In the node N2, the second phase radio frequency signal RF1-2 having passed through the phase shifter 4 and the second phase radio frequency signal RF2-2 are superposed on each other.

The balun 5 includes the first winding 21 and a second winding 22.

One end of the first winding 21 is electrically connected to the node N1. Another end of the first winding 21 is electrically connected to the node N2. A midpoint of the first winding 21 is electrically connected to the power source potential. The second winding 22 is magnetically coupled to the first winding 21. The first phase radio frequency signal RFout1 is outputted from one end of the second winding 22. The second phase radio frequency signal RFout2 is outputted from another end of the second winding 22.

### Layout of First Comparative Example

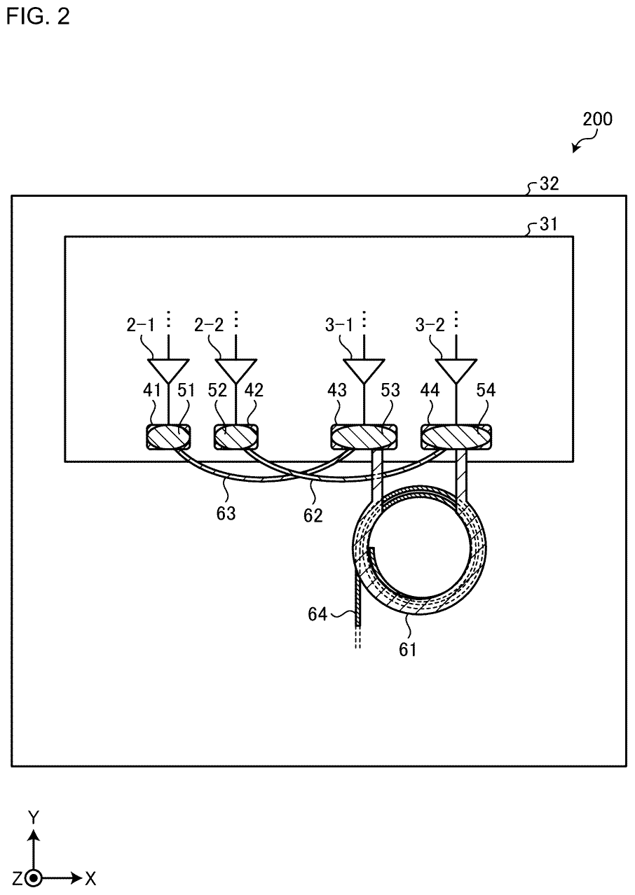

FIG. 2 illustrates a layout of a Doherty amplifier according to a first comparative example. FIG. 2 is a schematic plan view of a Doherty amplifier 200 according to the first comparative example seen in a direction perpendicular to a main surface of the Doherty amplifier 200.

The Doherty amplifier 200 is a printed circuit board in which the IC 31 is mounted on the printed wiring board 32. The main surface of the printed wiring board 32 extends along the X-Y plane. A first side of the printed wiring board 32 and a second side of the printed wiring board 32 which is the opposite side of the first side extend along the X direction. A third side of the printed wiring board 32 and a fourth side of the printed wiring board 32 which is the opposite side of the third side extend along the Y direction.

The first phase amplifier 2-1, the second phase amplifier 2-2, the first phase amplifier 3-1, and the second phase amplifier 3-2 are formed in the IC 31.

The first phase amplifier 2-1 and the second phase amplifier 2-2 are disposed next to each other in consideration of symmetry of the inductance. Disposing the first phase amplifier 2-1 and the second phase amplifier 2-2 next to each other means that no other amplifier is disposed between the first phase amplifier 2-1 and the second phase amplifier 2-2 and does not prohibit the existence of an element other than the amplifier. Likewise, the first phase amplifier 3-1 and the second phase amplifier 3-2 are disposed next to each other.

The first phase amplifier 2-1 to the second phase amplifier 3-2 are arranged on a straight line along the X direction. That is, the second phase amplifier 2-2 and the first phase amplifier 3-1 are disposed next to each other.

Referring to FIG. 2, the first phase amplifier 2-1, the second phase amplifier 2-2, the first phase amplifier 3-1, and the second phase amplifier 3-2 are arranged in this order along the X direction. However, the present disclosure is not limited to this. For example, the second phase amplifier 2-2, the first phase amplifier 2-1, the second phase amplifier 3-2, and the first phase amplifier 3-1 may be arranged in this order. Alternatively, for example, the first phase amplifier 3-1, the second phase amplifier 3-2, the first phase amplifier 2-1, and the second phase amplifier 2-2 may be arranged in this order. Alternatively, for example, the second phase amplifier 3-2, the first phase amplifier 3-1, the second phase amplifier 2-2, and the first phase amplifier 2-1 may be arranged in this order.

That is, it is sufficient that the first phase amplifier 2-1 and the second phase amplifier 3-2 be formed next to each other, or the second phase amplifier 2-2 and the first phase amplifier 3-1 be formed next to each other.

A metal portion 41 (metal electrode) is formed on a lower surface (surface on the back side of the page) of the IC 31. The metal portion 41 is electrically connected to an output terminal (the collector of the transistor Q1 (see FIG. 1)) of the first phase amplifier 2-1. A bump 51 is formed below (back side of the page) the metal portion 41.

A metal portion 42 is formed on the lower surface of the IC 31. The metal portion 42 is electrically connected to an output terminal (the collector of the transistor Q2 (see FIG. 1)) of the second phase amplifier 2-2. A bump 52 is formed below the metal portion 42.

A metal portion 43 is formed on the lower surface of the IC 31. The metal portion 43 is electrically connected to an output terminal (the collector of the transistor Q3 (see FIG. 1)) of the first phase amplifier 3-1. A bump 53 is formed below the metal portion 43.

A metal portion 44 is formed on the lower surface of the IC 31. The metal portion 44 is electrically connected to an output terminal (the collector of the transistor Q4 (see FIG. 1)) of the second phase amplifier 3-2. A bump 54 is formed in a lower portion of the metal portion 44.

The metal portions 41 to 44 are arranged on a straight line along the X direction. The bumps 51 to 54 are arranged on a straight line along the X direction. The metal portions 41 to 44 may be referred to as metal electrodes or under bump metal (UBM). The metal portions 41 to 44 are formed of, for example, a material that includes at least one of Ti, Cr, Cu, Au, Ni, and Pd. The bumps 51 to 54 are, for example, pillar bumps and, for example, copper (Cu) is used for the bumps 51 to 54. Instead of copper, a low-resistance metal material such as aluminum (Al) or gold (Au) may be used for the bumps 51 to 54. The bumps 51 to 54 may be, for example, solder bumps or stud bumps.

The IC 31 is electrically connected to the printed wiring board 32 via the bumps 51 to 54.

A first winding 61 of the balun 5 (corresponding to the first winding 21 (see FIG. 1)) is formed on a first metal layer (metal layer on the very front side of the paper) of the printed wiring board 32. One end of the first winding 61 is electrically connected to the bump 53. Another end of the first winding 61 is electrically connected to the bump 54. A second winding 64 of the balun 5 is formed on a layer below the first winding 61 (a second metal layer (a metal layer immediately on the back side of the first metal layer in the page)).

A wiring 62 (corresponding to the inductor 12 (see FIG. 1)) is formed on the second metal layer (the metal layer immediately on the back side of the first metal layer in the page) of the printed wiring board 32. One end of the wiring 62 is electrically connected to the bump 52. Another end of the wiring 62 is electrically connected to the bump 54.

A wiring 63 (corresponding to the inductor 11 (see FIG. 1)) is formed on a third metal layer (a metal layer immediately on the back side of the second metal layer in the page) of the printed wiring board 32. One end of the wiring 63 is electrically connected to the bump 51. Another end of the wiring 63 is electrically connected to the bump 53.

As illustrated in FIG. 2, when the wirings 62 and 63 are formed on the printed wiring board 32, at least one of the wirings 62 and 63 needs to detour around the bump. Accordingly, in the Doherty amplifier 200, it is difficult to reduce wiring lengths of the wirings 62 and 63. That is, in the Doherty amplifier 200, it is difficult to suppress inductance values of the wirings 62 and 63.

As described above, it is difficult to suppress inductance values of the wirings 62 and 63, and accordingly, it is difficult for the Doherty amplifier 200 to correspond to the case where the frequency of the radio-frequency signal is high. As a result of the difficulty of the suppression of the inductance values of the wirings 62 and 63, it is difficult for the Doherty amplifier 200 to suppress characteristic impedance of the phase shifter 4. Accordingly, it is difficult to increase output of the Doherty amplifier 200.

In the Doherty amplifier 200, when the frequency of the radio-frequency signal is increased or the characteristic impedance of the phase shifter 4 is reduced, the inductance values of the wirings 62 and 63 need to be reduced (at the same time, the electrostatic capacity values of the capacitors 13 and 14 need to be increased).

### Layout of Second Comparative Example

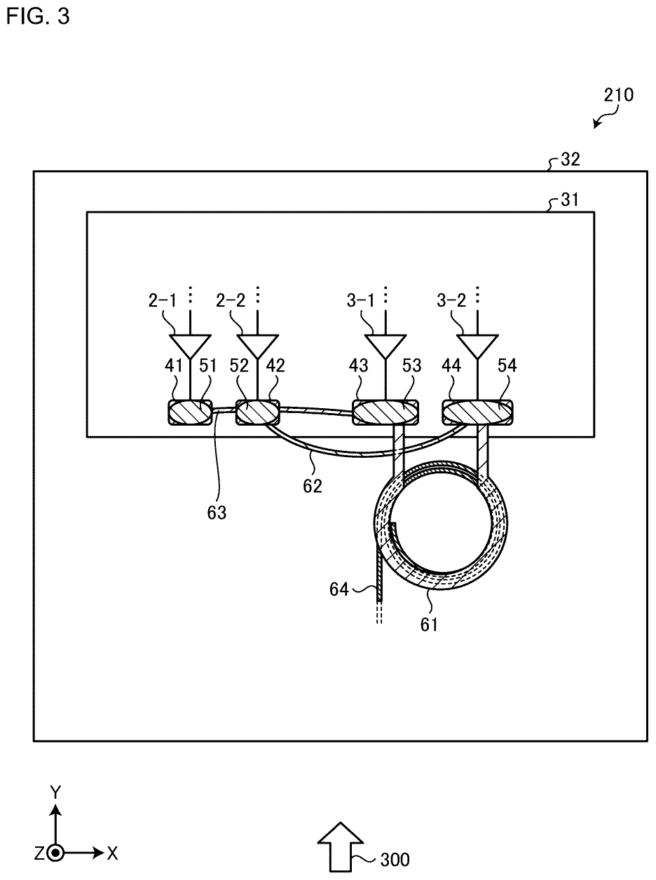

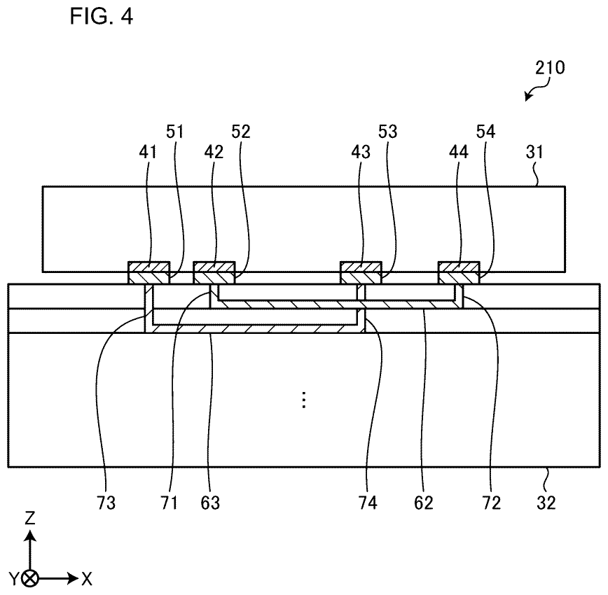

FIGS. 3 and 4 illustrate a layout of a Doherty amplifier according to a second comparative example. FIG. 3 is a schematic plan view of a Doherty amplifier 210 according to the second comparative example seen in a direction perpendicular to a main surface of the Doherty amplifier 210. FIG. 4 is a schematic side view of the Doherty amplifier 210 seen in a direction parallel to the main surface of the Doherty amplifier 210 (direction of arrow 300 illustrated in FIG. 3). Illustration of the first winding 61 and the second winding 64 is omitted from the schematic side view of FIG. 4.

Referring to FIG. 3, compared to the Doherty amplifier 200 according to the first comparative example, the wiring 63 is formed to have a minimum distance (linearly) from below (back side in the page of) the bump 51 to below (back side in the page of) the bump 53 in the Doherty amplifier 210 according to the second comparative example for suppressing the inductance value.

Referring to FIG. 4, the one end of the wiring 62 is electrically connected to the bump 52 via a via 71. The other end of the wiring 62 is electrically connected to the bump 54 via a via 72. The one end of the wiring 63 is electrically connected to the bump 51 via a via 73. The other end of the wiring 63 is electrically connected to the bump 53 via a via 74.

Referring to FIGS. 3 and 4, the wiring 62 needs to detour around the bump 53 and the via 74. Thus, the wiring 62 cannot be linearly formed.

From the viewpoint of the symmetry of the inductance values of the first phase and the second phase, the inductance values of the wiring 62 and the wiring 63 may be the same. That is, the wiring lengths of the wiring 62 and the wiring 63 may be the same.

In the Doherty amplifier 210, the symmetry cannot be secured as long as the wiring 62 cannot be linearly formed even when the wiring 63 is linearly formed. For securing the symmetry, in the Doherty amplifier 210, the wiring length of the wiring 63 needs to be increased (to have the same wiring length as that of the wiring 62), and the wiring 63 cannot be linearly formed. That is, in the Doherty amplifier 210, it is difficult to suppress the inductance values of both the wiring 62 and the wiring 63.

### Layout of First Embodiment

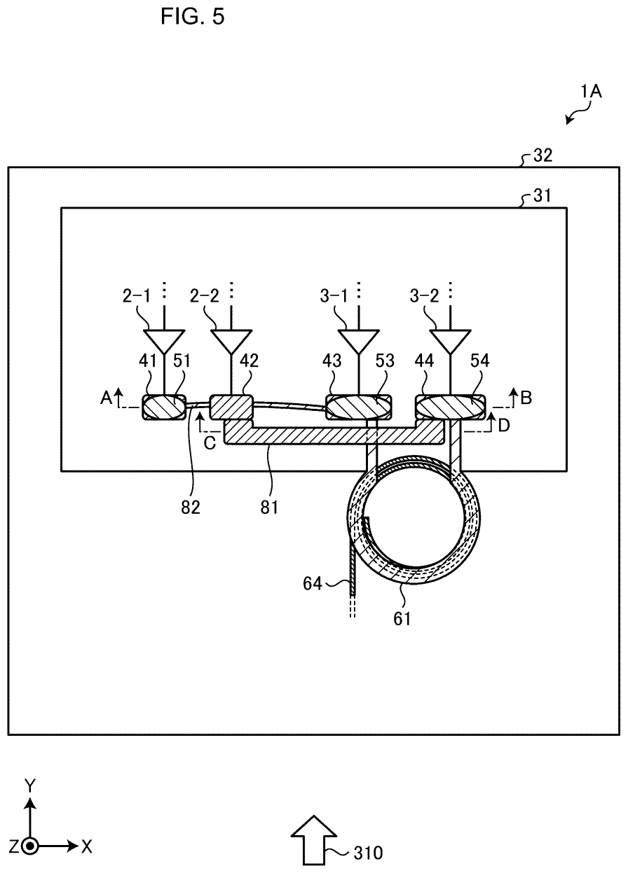

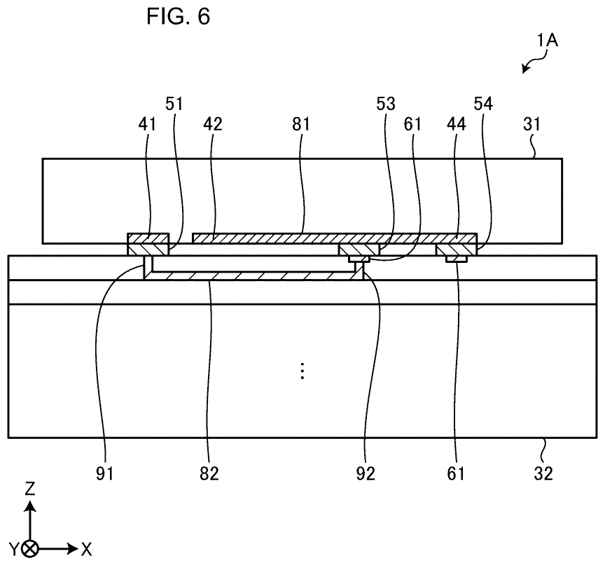

FIGS. 5 and 6 illustrate a layout of a Doherty amplifier according to a first embodiment. FIG. 5 is a schematic plan view of a Doherty amplifier 1A according to the first embodiment seen in a direction perpendicular to a main surface of the Doherty amplifier 1A.

FIG. 6 is a schematic side view of the Doherty amplifier 1A seen in a direction parallel to the main surface of the Doherty amplifier 1A (direction of arrow 310 illustrated in FIG. 5). FIG. 6 illustrates the sections of the metal portions 41 to 44, the bumps 51, 53, and 54, and a wiring 82 taken along line A-B illustrated in FIG. 5. FIG. 6 also illustrates the sections of a wiring 81 and the first winding 61 taken along line C-D illustrated in FIG. 5.

Referring to FIG. 5, compared to the first comparative example and the second comparative example, the bump is not formed on the metal portion 42 of the IC 31 of the Doherty amplifier 1A. In the Doherty amplifier 1A, the wiring 81 is formed on the lower surface (surface on the back side of the page) of the IC 31. One end of the wiring 81 is electrically connected to the metal portion 42. Another end of the wiring 81 is electrically connected to the metal portion 44. For example, copper (Cu) is used for the wiring 81. Instead of Cu, a low-resistance metal material such as aluminum (Al) or gold (Au) may be used for the wiring 81.

The wiring 81 corresponds to an example of a “second wiring” of the present disclosure.

Furthermore, in the Doherty amplifier 1A, the wiring 82 is formed to have a minimum distance (linearly) from below the bump 51 to below the bump 53 in the second metal layer of the printed wiring board 32. For example, copper (Cu) is used for the wiring 82. Instead of Cu, a low-resistance metal material such as aluminum (Al) or gold (Au) may be used for the wiring 82.

The wiring 82 corresponds to an example of a “first wiring”of the present disclosure.

Referring to FIG. 6, the wiring 81 is formed on the lower surface of the IC 31. One end of the wiring 82 is electrically connected to the bump 51 via a via 91. The other end of the wiring 82 is electrically connected to the bump 53 via a via 92.

Although the wiring 82 is formed on the second metal layer of the printed wiring board 32 according to the embodiment, the present disclosure is not limited to this. The wiring 82 may be formed on, for example, the first metal layer of the printed wiring board 32. In this case, neither the via 91 nor the via 92 is necessary. Furthermore, one end of the wiring 82 is electrically connected to the bump 51, and the other end of the wiring 82 is electrically connected to the bump 53.

### Effects of First Embodiment

The bumps have a certain degree of inductance. In the Doherty amplifier 1A, the one end of the wiring 81 is directly connected to the metal portion 42 without the bump interposed therebetween. The other end of the wiring 81 is directly connected to the metal portion 44 without the bump 54 interposed therebetween. Accordingly, the Doherty amplifier 1A can suppress the inductance value of a path extending through the metal portion 42, the wiring 81, and the metal portion 44 (hereinafter, referred to as a first path) by a value corresponding to two bumps.

Although the wiring 81 needs to detour around the bump 53, the detouring distance can be reduced compared to the wiring 62 of the first comparative example and the second comparative example (see FIGS. 2 and 3). Accordingly, the Doherty amplifier 1A can suppress the inductance value of the first path by a value corresponding to the reduction of the detouring distance compared to the wiring 62.

The length of the via 91 and the via 92 can be reduced compared to the length of the via 73 and the via 74 (see FIG. 4). Accordingly, compared to the first comparative example and the second comparative example, the Doherty amplifier 1A can suppress the inductance value of a path extending through the metal portion 41, the bump 51, the via 91, the wiring 82, the via 92, the bump 53, and the metal portion 43 (hereinafter, referred to as a second path). Furthermore, in the Doherty amplifier 1A, when the wiring 82 is formed on the first metal layer of the printed wiring board 32, neither the via 91 nor the via 92 is necessary. Accordingly, the Doherty amplifier 1A can further suppress the inductance value of the second path.

From the viewpoint of the symmetry, the inductance value of the first path and the inductance value of the second path may be the same. Accordingly, in the Doherty amplifier 1A, it is sufficient that the inductance value of one of the first path and the second path with a smaller inductance value be adjusted to the inductance value of the other of the first path and the second path with a greater inductance value by, for example, increasing the wiring length or reducing a wiring width.

As described above, compared to the first comparative example and the second comparative example, the Doherty amplifier 1A can suppress the inductance values of the first path and the second path, and accordingly, the Doherty amplifier 1A can correspond to the case where the frequency of the radio-frequency signal is high.

Furthermore, because the Doherty amplifier 1A can suppress the inductance values of the first path and the second path, the characteristic impedance of the phase shifter 4 can be reduced. Accordingly, the output can be increased.

### Appendix

In the Doherty amplifier 1A, the metal portion 42 and the metal portion 44 are electrically connected to each other via the wiring 81 (second wiring) formed in the IC 31, and the metal portion 41 and the metal portion 43 are electrically connected to each other via the wiring 82 (first wiring) formed on the printed wiring board 32. However, the present disclosure is not limited to this. The metal portion 41 and the metal portion 43 may be electrically connected to each other via the first wiring formed in the IC 31, and the metal portion 42 and the metal portion 44 may be electrically connected to each other via the second wiring formed on the printed wiring board 32. That is, it is sufficient that one of the first wiring and the second wiring be formed in the IC 31, and the other of the first wiring and the second wiring be formed on the printed wiring board 32.

### Second Embodiment

According to a second embodiment, the symmetry of the inductance is considered. For comparison with the second embodiment, the inductance according to the first embodiment is described.

Equivalent Circuit Diagram Focusing on Inductance according to First Embodiment

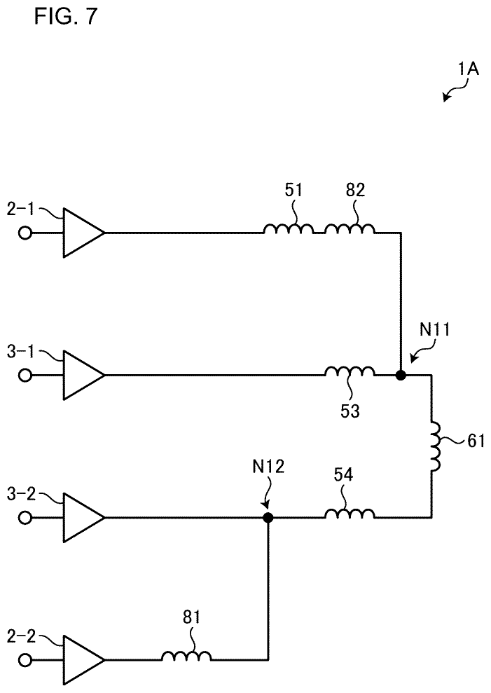

FIG. 7 is an equivalent circuit diagram focusing on the inductance of the Doherty amplifier according to the first embodiment.

An output terminal of the first phase amplifier 2-1 is electrically connected to a node N11 (a joint between the via 92 and the one end of the first winding 61) via the bump 51 and the wiring 82.

An output terminal of the first phase amplifier 3-1 is electrically connected to the node N11 via the bump 53.

An output terminal of the second phase amplifier 2-2 is electrically connected to a node N12 (the metal portion 44) via the wiring 81.

An output terminal of the second phase amplifier 3-2 is electrically connected to the node N12.

The one end of the first winding 61 is electrically connected to the node N11. The other end of the first winding 61 is electrically connected to the node N12 via the bump 54.

As illustrated in FIG. 7, in the Doherty amplifier 1A according to the first embodiment, the node N11 to which the other end of the wiring 82 is electrically connected is between the bump 53 and the first winding 61. Meanwhile, the node N12 to which the other end of the wiring 81 is electrically connected is between the output terminal of the second phase amplifier 3-2 and the bump 54. That is, in the Doherty amplifier 1A, a connecting manner of the first phase and a connecting manner of the second phase are not symmetric.

Accordingly, in the Doherty amplifier 1A according to the first embodiment, it is not easy to ensure the symmetry of the inductance of the first phase and the inductance of the second phase.

### Layout of Second Embodiment

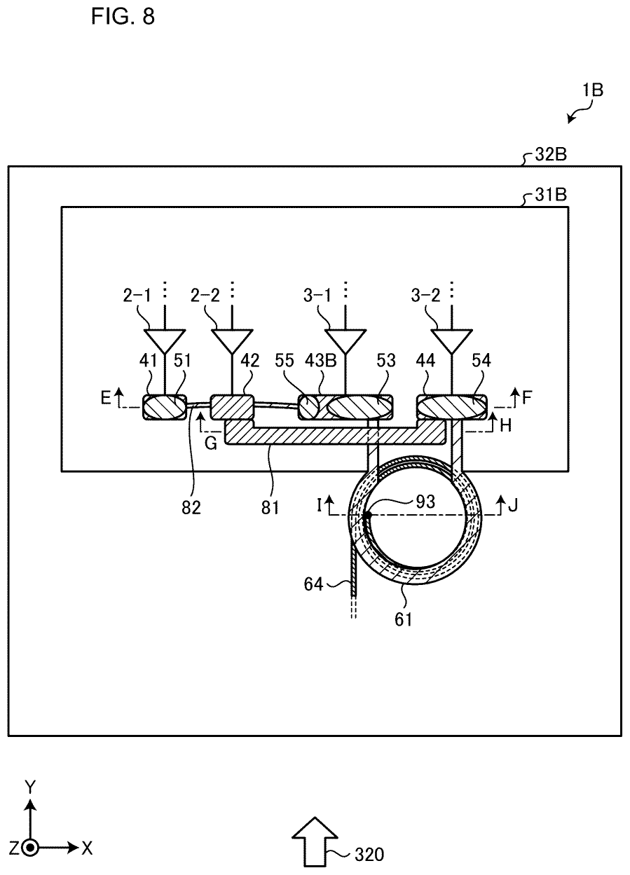

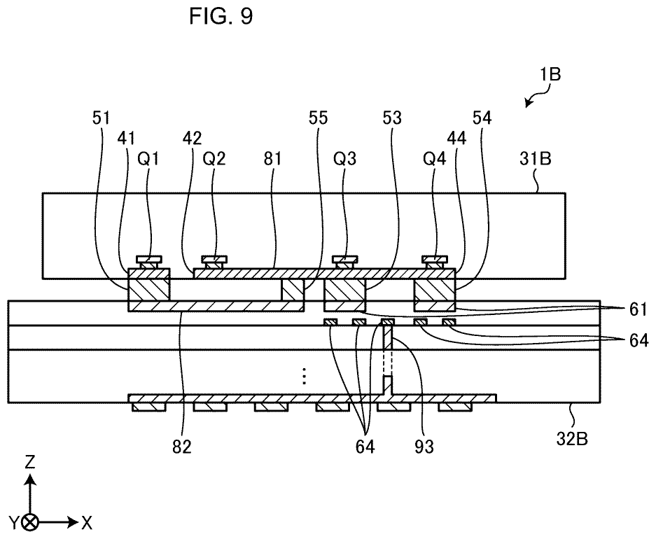

FIGS. 8 and 9 illustrate a layout of a Doherty amplifier according to a second embodiment. FIG. 8 is a schematic plan view of a Doherty amplifier 1B according to the second embodiment seen in a direction perpendicular to a main surface of the Doherty amplifier 1B.

FIG. 9 is a schematic side view of the Doherty amplifier 1B seen in a direction parallel to the main surface of the Doherty amplifier 1B (direction of arrow 320 illustrated in FIG. 8). FIG. 9 also illustrates the sections of the metal portions 41 to 44, the bumps 51, 55, 53, and 54, and the wiring 82 taken along line E-F illustrated in FIG. 8. FIG. 9 also illustrates the section of the wiring 81 taken along line G-H illustrated in FIG. 8. FIG. 9 also illustrates the sections of the first winding 61 and the second winding 64 taken along line I-J illustrated in FIG. 8. One end of the second winding 64 is electrically connected to a via 93.

The Doherty amplifier 1B is a printed circuit board in which an IC 31B is mounted on a printed wiring board 32B.

Referring to FIG. 8, compared to the Doherty amplifier 1A according to the first embodiment, the length of a metal portion 43B of the IC 31B is increased in the X direction, and the metal portion 43B has a wiring shape in the Doherty amplifier 1B. Furthermore, in addition to the bump 53, a bump 55 is formed below (the back side of the page) the metal portion 43B. The other end of the wiring 82 is electrically connected to the bump 55.

The bump 54 corresponds to an example of a “first bump” of the present disclosure. The bump 51 corresponds to an example of a “second bump”of the present disclosure.

The bump 55 corresponds to an example of a “third bump” of the present disclosure. The bump 53 corresponds to an example of a “fourth bump” of the present disclosure. The metal portion 43B corresponds to an example of a “third wiring”of the present disclosure.

Referring to FIG. 9, the one end of the wiring 82 is electrically connected to the bump 51. The other end of the wiring 82 is electrically connected to the bump 55.

Equivalent Circuit Diagram Focusing on Inductance according to Second Embodiment

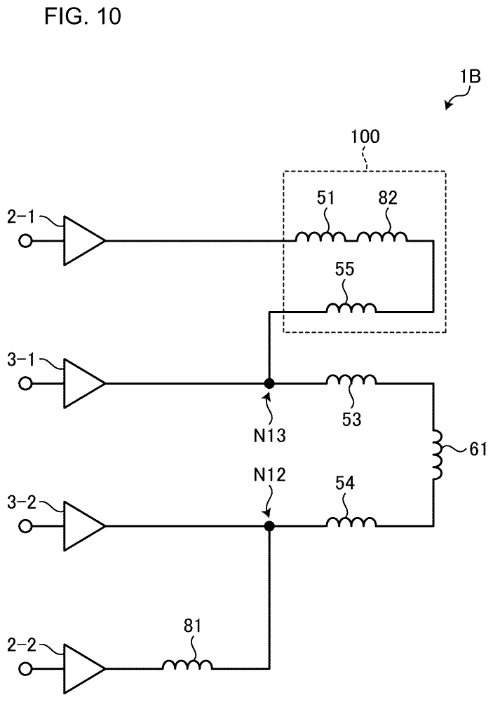

FIG. 10 is an equivalent circuit diagram focusing on the inductance of the Doherty amplifier according to the second embodiment.

The output terminal of the first phase amplifier 2-1 is electrically connected to a node N13 (metal portion 43B) via the bump 51, the wiring 82, and the bump 55. The bump 51, the wiring 82, and the bump 55 can be regarded as a single series circuit 100 (a single inductance).

The output terminal of the first phase amplifier 3-1 is electrically connected to the node N13.

The output terminal of the second phase amplifier 2-2 is electrically connected to the node N12 (the metal portion 44) via the wiring 81.

The output terminal of the second phase amplifier 3-2 is electrically connected to the node N12.

The one end of the first winding 61 is electrically connected to the node N13 via the bump 53. The other end of the first winding 61 is electrically connected to the node N12 via the bump 54.

### Effects of Second Embodiment

In the Doherty amplifier 1B, when the inductance value of the series circuit 100 and the inductance value of the wiring 81 are the same, the connection of the first phase and the connection of the second phase are symmetric. The inductance value of the series circuit 100 and the inductance value of the wiring 81 are easily set to be the same.

Thus, degradation of the output characteristics of the Doherty amplifier 1B is easily suppressed.

### Example of Configuration of Present Disclosure

The present disclosure can be configured as follows.
(1) A Doherty amplifier includes a carrier amplifier and a peak amplifier. Each of the carrier amplifier and the peak amplifier is a differential amplifier including a first phase amplifier and a second phase amplifier. The Doherty amplifier also includes a balun configured to synthesize an output signal of the carrier amplifier and an output signal of the peak amplifier. The carrier amplifier and the peak amplifier are formed in an integrated circuit. The balun is formed on a printed wiring board on which the integrated circuit is mounted. When a first wiring electrically connects an output terminal of the first phase amplifier of the carrier amplifier and an output terminal of the first phase amplifier of the peak amplifier to each other, and a second wiring electrically connects an output terminal of the second phase amplifier of the carrier amplifier and an output terminal of the second phase amplifier of the peak amplifier to each other, one of the first wiring and the second wiring is formed on the printed wiring board and another of the first wiring and the second wiring is formed in the integrated circuit.
(2) In the Doherty amplifier according to (1) described above, the integrated circuit is electrically connected to the printed wiring board by using a plurality of bumps. The plurality of bumps include a first bump electrically connected to the wiring out of the first wiring and the second wiring formed in the integrated circuit, a second bump electrically connecting between one end of the wiring out of the first wiring and the second wiring formed on the printed wiring board and the output terminal of the first phase amplifier of the carrier amplifier, and a third bump electrically connecting between another end of the wiring out of the first wiring and the second wiring formed on the printed wiring board and the output terminal of the first phase amplifier of the peak amplifier.
(3) In the Doherty amplifier according to (2) described above, the third bump is electrically connected to a fourth bump electrically connecting between the output terminal of the first phase amplifier of the peak amplifier and the balun via a third wiring formed in the integrated circuit.
(4) In the Doherty amplifier according to any one of (1) to (3) described above, the first phase amplifier and the second phase amplifier of the carrier amplifier are formed next to each other, the first phase amplifier and the second phase amplifier of the peak amplifier are formed next to each other, and the first phase amplifier of the carrier amplifier and the second phase amplifier of the peak amplifier are formed next to each other, or the second phase amplifier of the carrier amplifier and the first phase amplifier of the peak amplifier are formed next to each other.

The above-described embodiments are for ease of understanding of the present disclosure, but not for interpretation of the present disclosure by limiting the present disclosure. The present disclosure can be changed/modified without departing from the gist thereof, and the present disclosure includes equivalents thereof.
1, 1A, 1B, 200, 210 Doherty amplifier
2 carrier amplifier
2-1, 3-1 first phase amplifier
2-2, 3-2 second phase amplifier
3 peak amplifier
4 phase shifter
5 balun
11, 12 inductor
13, 14 capacitor
21, 61 first winding
22, 64 second winding
31, 31B integrated circuit
32, 32B printed wiring board
41, 42, 43, 43B, 44 metal portion
51, 52, 53, 54, 55 bump
62, 63, 81, 82 wiring
71, 72, 73, 74, 91, 92, 93 via

1. A Doherty amplifier comprising:
a carrier amplifier and a peak amplifier, the carrier amplifier and the peak amplifier each being a differential amplifier comprising a first phase amplifier and a second phase amplifier; and
a balun configured to synthesize an output signal of the carrier amplifier and an output signal of the peak amplifier,
wherein the carrier amplifier and the peak amplifier are formed in an integrated circuit,
wherein the balun is formed on a printed wiring board on which the integrated circuit is mounted, and
wherein a first wiring electrically connects an output terminal of the first phase amplifier of the carrier amplifier and an output terminal of the first phase amplifier of the peak amplifier to each other,
wherein a second wiring electrically connects an output terminal of the second phase amplifier of the carrier amplifier and an output terminal of the second phase amplifier of the peak amplifier to each other, and
wherein one of the first wiring and the second wiring is formed on the printed wiring board and another of the first wiring and the second wiring is formed in the integrated circuit.

2. The Doherty amplifier according to claim 1,
wherein the integrated circuit is electrically connected to the printed wiring board with a plurality of bumps, and
wherein the plurality of bumps comprise:
a first bump electrically connected to the wiring the first wiring or the second wiring that is formed in the integrated circuit,
a second bump electrically connected between a first end of the first wiring or the second wiring that is formed on the printed wiring board, and an output terminal of the first phase amplifier of the carrier amplifier, and
a third bump electrically connected between a second end of the first wiring or the second wiring that is formed on the printed wiring board, and the output terminal of the first phase amplifier of the peak amplifier.

3. The Doherty amplifier according to claim 2,
wherein the third bump is electrically connected to a fourth bump, and
wherein the fourth bump is electrically connected between the output terminal of the first phase amplifier of the peak amplifier and the balun via a third wiring formed in the integrated circuit.

4. The Doherty amplifier according to claim 1,
wherein the first phase amplifier and the second phase amplifier of the carrier amplifier are formed next to each other,
wherein the first phase amplifier and the second phase amplifier of the peak amplifier are formed next to each other, and
wherein the first phase amplifier of the carrier amplifier and the second phase amplifier of the peak amplifier are formed next to each other, or the second phase amplifier of the carrier amplifier and the first phase amplifier of the peak amplifier are formed next to each other.

5. The Doherty amplifier according to claim 2,
wherein the first phase amplifier and the second phase amplifier of the carrier amplifier are formed next to each other,
wherein the first phase amplifier and the second phase amplifier of the peak amplifier are formed next to each other, and
wherein the first phase amplifier of the carrier amplifier and the second phase amplifier of the peak amplifier are formed next to each other, or the second phase amplifier of the carrier amplifier and the first phase amplifier of the peak amplifier are formed next to each other.

6. The Doherty amplifier according to claim 3,
wherein the first phase amplifier and the second phase amplifier of the carrier amplifier are formed next to each other,
wherein the first phase amplifier and the second phase amplifier of the peak amplifier are formed next to each other, and
wherein the first phase amplifier of the carrier amplifier and the second phase amplifier of the peak amplifier are formed next to each other, or the second phase amplifier of the carrier amplifier and the first phase amplifier of the peak amplifier are formed next to each other.
